(19) United States
(12) Patent Application Publication
(10) Pub. No.: US 2009/0174438 A1
(43) Pub. Date: Jul. 9, 2009

(54) Data Trigger Reset Device and Related Method

(76) Inventors: Jin-Ho Lin, Kao-Hsiung City (TW); Cheng-Hsun Chan, Taipei County (TW); Che-Li Lin, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/142,755

(22) Filed: Jun. 19, 2008

(30) Foreign Application Priority Data
Jan. 3, 2008 (TW) 097100195

(51) Int. Cl. H03K 5/22

(52) U.S. Cl. 327/77

(57) ABSTRACT

A data trigger reset device for an electronic device is provided in order to avoid system errors due to out-of-sequence reset on electronic devices of an electronic system. The data trigger reset device includes a voltage converter and a voltage comparator. The voltage converter receives an input signal and then converts the input signal to generate a data voltage signal. The voltage comparator is coupled to the voltage converter and is used for comparing the data voltage signal with a reference voltage to generate a reset signal for resetting the electronic device.

### BACKGROUND OF THE INVENTION

1. Field of the Invention

The present invention relates to a reset device and related method, and more particularly to an electronic device and related method for triggering reset by voltage comparison.

2. Description of the Prior Art

Electronic devices in an electronic system shall be reset timely and properly in order to ensure normal operations. A typical reset circuit utilizes power-on reset, which operates with capacitive and resistive fundamental devices. In this way, the electronic system requires power on sequence to prevent the electronic devices from receiving invalid data.

Please refer to FIG. 1 and FIG. 2, which are respectively schematic diagrams of reset circuits 100 and 200 according to the prior art. In FIG. 1, a capacitor C is coupled to a supply voltage VCC and a resistor R is coupled to a grounded terminal. In general, the reset circuit 100 generates a positive reset signal RS1 with a high voltage level since the capacitor C is charged to the supply voltage VCC. As the capacitor C begins to discharge, the positive reset signal RS1 gradually decreases in voltage, and the reset circuit 100 accomplishes the reset operation when a voltage level of the positive reset signal RS1 reaches a low threshold level. Compared to FIG. 1, the capacitor C is coupled to the grounded terminal, and a resistor R is coupled to the supply voltage VCC in FIG. 2. In general, the reset circuit 200 generates a negative reset signal RS2 with a low voltage level and operates in a reset mode. As the capacitor C begins to charge, the negative reset signal RS2 gradually increases in voltage, and the reset circuit 200 accomplishes the reset operation when the voltage level of the negative reset signal RS2 reaches a high threshold level.

Taking a LCD display as an example. A typical driving circuit of a display includes a timing controller and a source driver. And an internal or external RC circuit of the source driver is installed for generating a reset signal and controlling reset timing. Please refer to FIG. 3, which is a schematic diagram of a timing controller 11 and a source driver 13 according to the prior art. Reset circuits 10 and 12 are respectively installed in the timing controller 11 and the source driver 13, and are the same type of reset circuit as the reset circuit 200 in FIG. 2. The reset circuit 10 includes a resistor RTCON and a capacitor CTCON and generates a reset signal TCON_reset for resetting the timing controller 11 according to a supply voltage TCON_VCC. The reset circuit 12 includes a resistor RSD and a capacitor CSD and generates a reset signal SD_reset for resetting the source driver 13 according to a supply voltage SD_VCC. In addition, the timing controller 11 can utilize differential signaling interface for transferring a data signal TCON_data to the source driver 13.

Please refer to FIGS. 4 and 5, which are schematic diagrams of signal waveforms of the timing controller 11 and the source driver 13 under different power-on sequences. In FIGS. 4 and 5, the signal waveforms from top to bottom are the supply voltages TCON_VCC and SD_VCC, the reset signals TCON_reset and SD_reset, and the data signal TCON_data. Assume that, in FIG. 4, the resistor RTCON is equal to the resistor RSD, and the capacitors CTCON and CSD provide same capacitance, and a time difference Tdr>0. Furthermore, the time point where the data signal TCON_data transits from an unstable state to a stable state falls between rising edges of the supply voltage TCON_VCC and the reset signal TCON_reset. As can be seen from FIG. 4, the voltage supplying time of the timing controller falls behind that of the source driver. The reset signal SD_reset rises to a high logic state earlier than the reset signal TCON_reset does, and thereby the source driver 13 accomplishes reset earlier than the timing controller 11 does.

In FIG. 5, assume that the resistor RTCON has the same resistance as the resistor RSD does, and the capacitor CTCON has a greater capacitance than the capacitor CSD does, and a time difference Tdr>0. Alternatively, assume the resistor RTCON has the same resistance as the resistor RSD does, and the capacitor CTCON has a greater capacitance than the capacitor CSD does, and a time difference Tdr>0. In the two abovementioned situations, the time point where the data signal TCON_data transits from the unstable state to the stable state falls between rising edges of the supply voltage TCON_VCC and the reset signal TCON_reset. As can be seen from FIG. 5, the voltage supplying times of the timing controller and the source driver are the same, and thereby the source driver 13 accomplishes reset earlier than the timing controller 11 does.

The data signal TCON_data in FIG. 4 or FIG. 5 are still at the unstable state when the source driver 13 accomplishes reset. In this situation, the source driver 13 begins to receive an invalid data segment of the data signal TCON_data, resulting in circuit operating errors.

Therefore, in the electronic system of the prior art, the time to power on affects reset-accomplished time of the electronic devices and could cause the electronic devices to receive invalid data signals. To improve this, the power on sequence for the electronic devices should be limited to certain sequence patterns, reducing system flexibility.

### SUMMARY OF THE INVENTION

The present invention provides a circuit device for an electronic device and related method that can determine a reset duration for the electronic device according to the received data signal.

The present invention discloses a data trigger reset device including a voltage converter and a voltage comparator for an electronic device. The voltage converter is used for receiving and converting an input signal to generate a data voltage signal. The voltage comparator is coupled to the voltage converter and used for comparing the data voltage signal with a reference voltage to generate a reset signal for resetting the electronic device.

The present invention further discloses a data trigger reset method for an electronic device. The data trigger reset method includes the following steps of receiving an input signal; converting the input signal to generate a data voltage signal; and comparing the data voltage signal with a reference voltage to generate a reset signal for resetting the electronic device.

The present invention further discloses a data trigger reset device including a timing controller and a source driver for a display. The timing controller is used for generating an input signal. The source driver is coupled to the timing controller and includes a voltage converter and a voltage comparator. The voltage converter is used for receiving and converting the input signal to generate a data voltage signal. The voltage comparator is coupled to the voltage converter and used for comparing the data voltage signal with a reference voltage to generate a reset signal for resetting the source driver.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a reset circuit according to the prior art.

FIG. 2 is a schematic diagram of a reset circuit according to the prior art.

FIG. 3 is a schematic diagram of a timing controller and a source driver according to the prior art.

FIG. 4 is a schematic diagram of signal waveforms of the timing controller and the source driver under different power-on sequences according to FIG. 3.

FIG. 5 is a schematic diagram of signal waveforms of the timing controller and the source driver under different power-on sequences according to FIG. 3.

FIG. 6 is a schematic diagram of a data trigger reset device for an electronic device according to an embodiment of the present invention.

FIG. 7 is a flow chart of a data trigger reset process for an electronic device according to an embodiment of the present invention.

FIG. 8 is a schematic diagram of a data trigger reset device for a display according to an embodiment of the present invention.

FIG. 9 is a flow chart of a data trigger reset process for a display according to an embodiment of the present invention.

FIGS. 10 to 12 are schematic diagrams of signal waveforms corresponding to the timing controller and the source driver under different power-on sequences according to the data trigger reset device in FIG. 8.

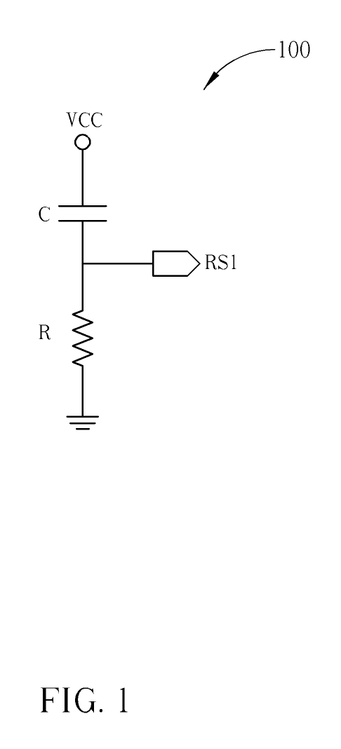

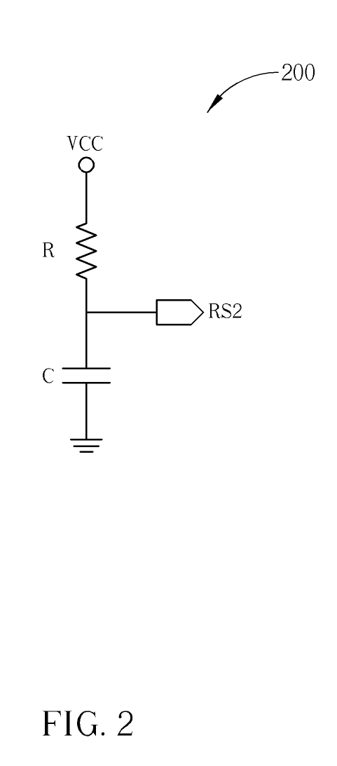

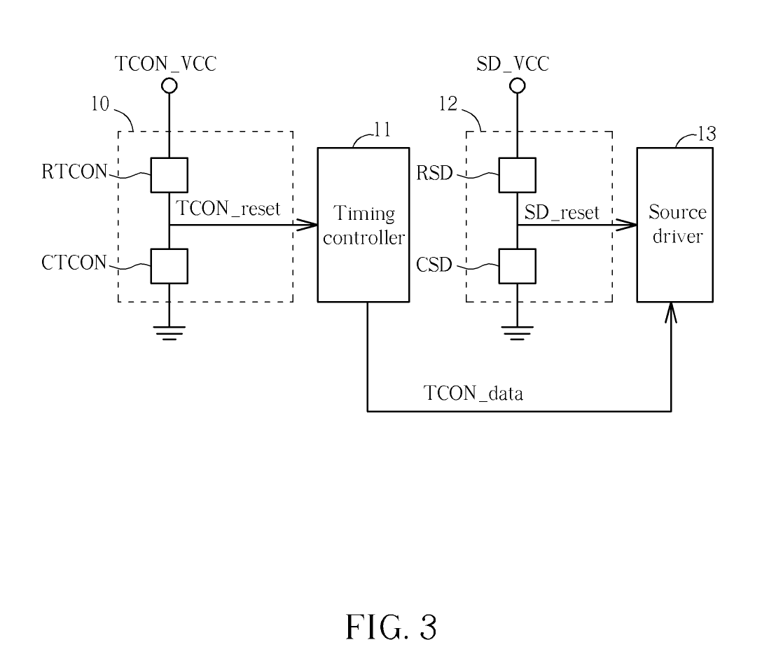

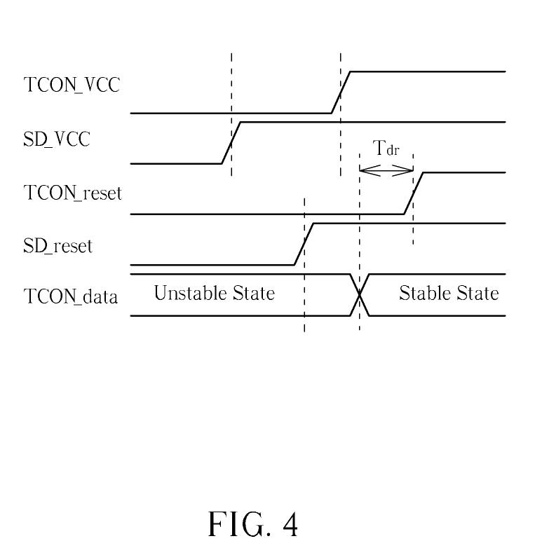

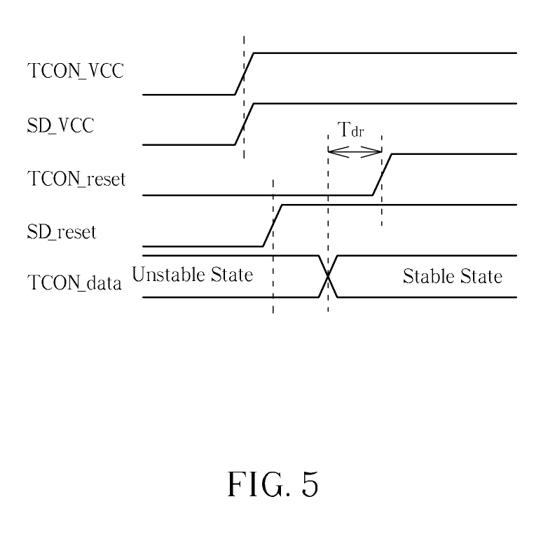

### DETAILED DESCRIPTION

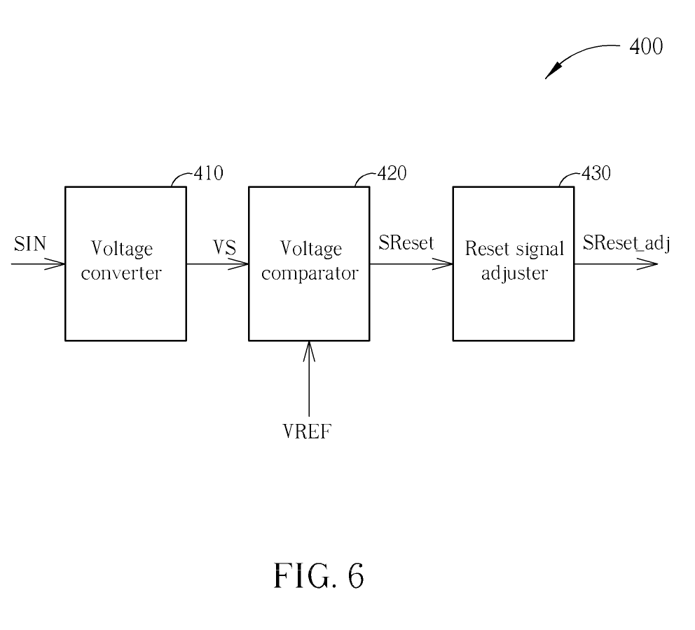

Please refer to FIG. 6, which is a schematic diagram of a data trigger reset device 400 for an electronic device according to an embodiment of the present invention. The data trigger reset device 400 includes a voltage converter 410, a voltage comparator 420 and a reset signal adjuster 430. The voltage converter 410 is used for receiving and converting an input signal SIN to generate a data voltage signal VS. The voltage comparator 420 is coupled to the voltage converter 410 and used for comparing the data voltage signal VS with a reference voltage VREF to generate a reset signal SReset. The reset signal adjuster 430 is coupled to the voltage comparator 420 and used for delaying the reset signal SReset to generate a reset adjusting signal SReset_adj.

For brevity, the data trigger reset device 400 controls a reset state of the electronic device by detecting a transition of the input signal SIN from the unstable state to the stable state. Therefore, the data trigger reset device 400 ensures that the reset of the electronic device is accomplished after the input signal SIN enters the stable state and thereby the electronic device can successfully receive data of the input signal SIN.

Through the data trigger reset device 400, those skilled in the art can determine whether to employ the reset signal adjuster 430 according to the system requirement. If the reset signal adjuster 430 is employed, the electronic device is reset with the reset adjusting signal SReset_adj. If the reset signal SReset fits the requirement of the electronic device, the reset signal SReset is directly used for resetting the electronic device. The data trigger reset device 400 obtains a suitable reset time according to the transition of the input signal SIN to avoid inaccurate data reception.

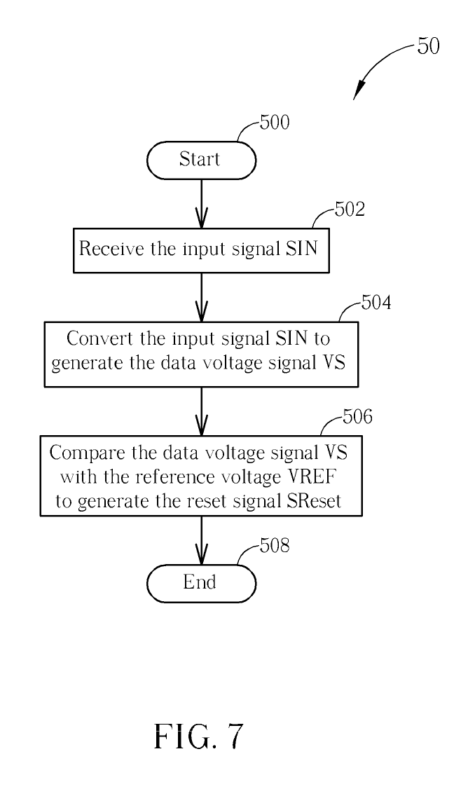

Please refer to FIG. 7, which is a flow chart of a data trigger reset process 50 for an electronic device according to an embodiment of the present invention. The data trigger reset process 50 is utilized to realize the data trigger reset device 400 for the suitable reset time and includes the following steps:

Step 500: Start.

Step 502: Receive the input signal SIN.

Step 504: Convert the input signal SIN to generate the data voltage signal VS.

Step 506: Compare the data voltage signal VS with the reference voltage VREF to generate the reset signal SReset.

Step 508: End.

In the data trigger reset process 50, the reset signal SReset is generated and the logic state thereof is determined according to a comparison result of the data voltage signal VS and the reference voltage VREF. For example, the reset signal SReset remains a low logic state when the data voltage signal VS is lower than the reference voltage VREF. On the contrary, the reset signal SReset rises to a high logic state when the data voltage signal VS becomes greater than the reference voltage VREF. The electronic device finishes the reset process when the reset signal SReset enters the high logic state. Please note that the reset timing can be adjusted according to the system requirement. The time the reset signal enters the high logic state can be postponed by delaying the reset signal SReset and thereby the reset adjusting signal SReset_adj is generated for resetting the electronic device. Since the data trigger reset process 50 is utilized to realize the data trigger reset device 400, the detailed operation is explained above in the description of the data trigger reset device 400.

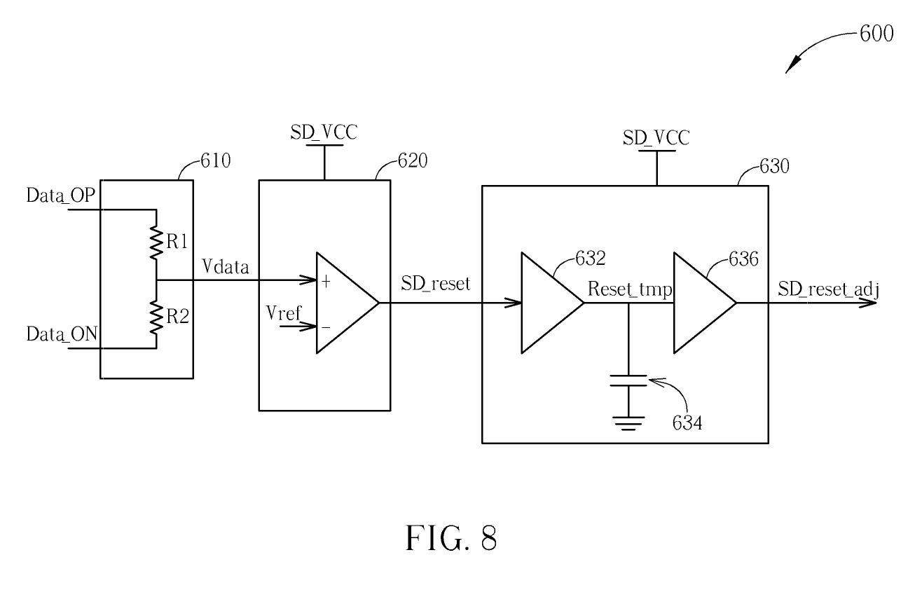

Preferably, the concept of the present invention can be applied to a driving circuit of a display. For simplicity, the reset operation of a timing controller and a source driver are used in the embodiment of the present invention. Please refer to FIG. 8, which is a schematic diagram of a data trigger reset device 600 according to an embodiment of the present invention. Data transmission lines Data_0P and Data_0N are coupled between the timing controller and the source driver for differential signal transfer. The differential signal can be a reduced swing differential signal (RSDS), a mini low voltage differential signal (mini-LVDS) or an embedded all in differential data-line signal (EDDS), where a EDDS signal has a property of multilevel currents and can be embedded with user-definable data represented by different current intensities and directions. As a result, the EDDS signal can generate multilevel voltage signal with positive or negative polarities at the source driver side. The data trigger reset device 600 is installed in the source driver and includes a voltage converter 610, a voltage comparator 620 and a reset signal adjuster 630. The voltage converter 610 is a voltage divider including resistors R1 and R2, and used for converting the differential signal to generate a data voltage signal Vdata. The voltage comparator 620 is a Schmitt trigger or a commonly used comparator and used for comparing the data voltage signal Vdata with a reference voltage Vref to generate a reset signal SD_reset. When the data voltage signal Vdata is greater than the reference voltage Vref, the reset signal SD_reset increases from a low logic level to a high logic level.

The reset signal adjuster 630 includes a buffer 632, a capacitor 634 coupled to the buffer 632 and a grounded terminal, and a Schmitt trigger 636. The reset signal adjuster 630 is used for delaying the reset signal SD_reset to generate a reset adjusting signal SD_reset_adj for resetting the source driver. The capacitor 634 generates a first voltage Reset_tmp according to the reset signal SD_reset. When the reset signal SD_reset enters the high logic state, the capacitor 634 begins to be charged through the buffer 632 until the first voltage Reset_tmp reaches a V+ voltage of the Schmitt trigger 636. Meanwhile, the reset adjusting signal SD_reset_adj is generated based on the first voltage Reset_tmp by the Schmitt trigger 636 to reset the source driver.

The differential signal outputted by the timing controller becomes stable and works normally when the data voltage signal Vdata is greater than the reference voltage Vref, and thereby the data trigger reset device 600 controls the reset process of the source driver according to the state variation of the differential signal. Therefore, the reset timing of the source driver always falls behind the reset timing of the timing controller to avoid data receiving errors. With the data trigger reset device 600, the power-on time of the timing controller is not limited to be earlier than the power-on time of the source driver.

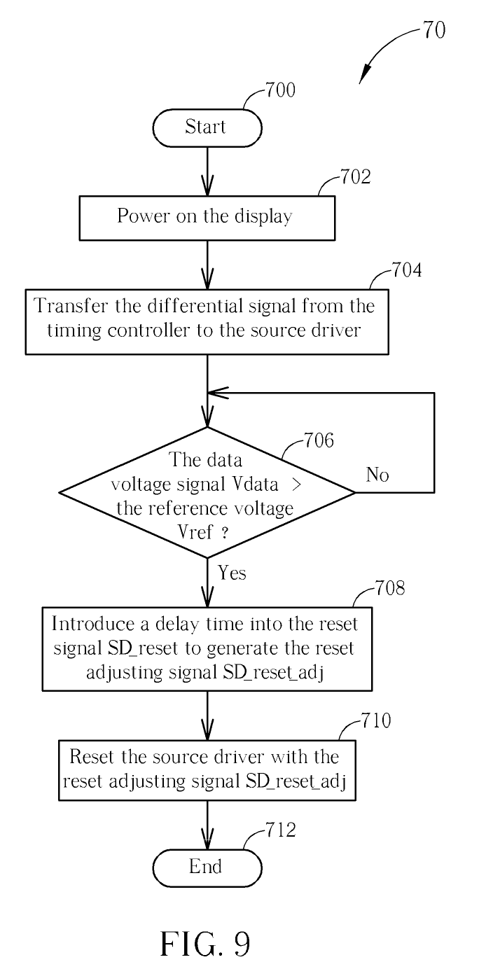

Please refer to FIG. 9, which is a flow chart of a data trigger reset process 70 for a display according to an embodiment of the present invention. The data trigger reset process 70 is utilized to realize the data trigger reset device 600 and includes the following steps:

Step 700: Start.

Step 702: Power on the display.

Step 704: Transfer the differential signal from the timing controller to the source driver.

Step 706: Determine whether the data voltage signal Vdata is greater than the reference voltage Vref. If so, perform Step 708; if not, perform Step 706 again.

Step 708: Introduce a delay time into the reset signal SD_reset to generate the reset adjusting signal SD_reset_adj.

Step 710: Reset the source driver with the reset adjusting signal SD_reset_adj.

Step 712: End.

According to the data trigger reset process 70, the differential signal gradually increases in voltage when the timing controller begins to transfer the differential signal. Meanwhile, the data voltage signal Vdata increases in voltage as well. When the data voltage signal Vdata is higher in voltage than the differential signal, the reset signal SD_reset is delayed according to a predetermine delay time so as to generate the reset adjusting signal SD_reset_adj, which is utilized to reset the source driver.

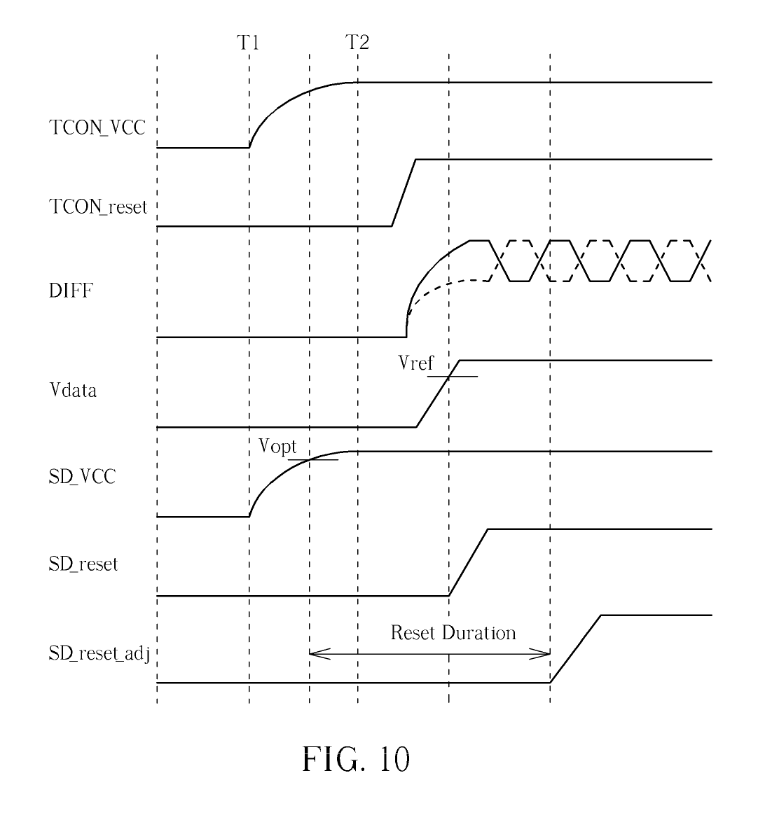

Please refer to FIGS. 10 to 12, which are schematic diagrams of signal waveforms corresponding to the timing controller and the source driver under different power-on sequences according to the data trigger reset device 600 in FIG. 8. In FIGS. 10-12, the signal waveforms from top to bottom are the supply voltage TCON_VCC, the reset signal TCON_reset, the differential signal DIFF, the data voltage signal Vdata, the supply voltage SD_VCC, the reset signal SD_reset and the reset adjusting signal SD_reset_adj. The supply voltages TCON_VCC and SD_VCC respectively activate provisions of clock timings for the timing controller and the source driver; the reset signal TCON_reset is utilized for resetting the timing controller; the data voltage signal Vdata is obtained from conversion of the differential signal DIFF; and the reset adjusting signal SD_reset_adj is generated by delaying the reset signal SD_reset for a predetermined time.

In FIG. 10, the supply voltages TCON_VCC and SD_VCC are both activated at the time point T1, and become stable after the time point T2. When the data voltage signal Vdata is over the reference voltage Vref, the reset signal SD_reset transits from the low to the high voltage level. The source driver begins to reset at the time point where the supply voltage SD_VCC is over a voltage level Vopt until the time point where the reset adjusting signal SD_reset_adj transits up to the high voltage level. From FIG. 10, the data voltage signal Vdata has become stable before the rising edge of the reset adjusting signal SD_reset_adj, and thereby the current differential signal includes valid data.

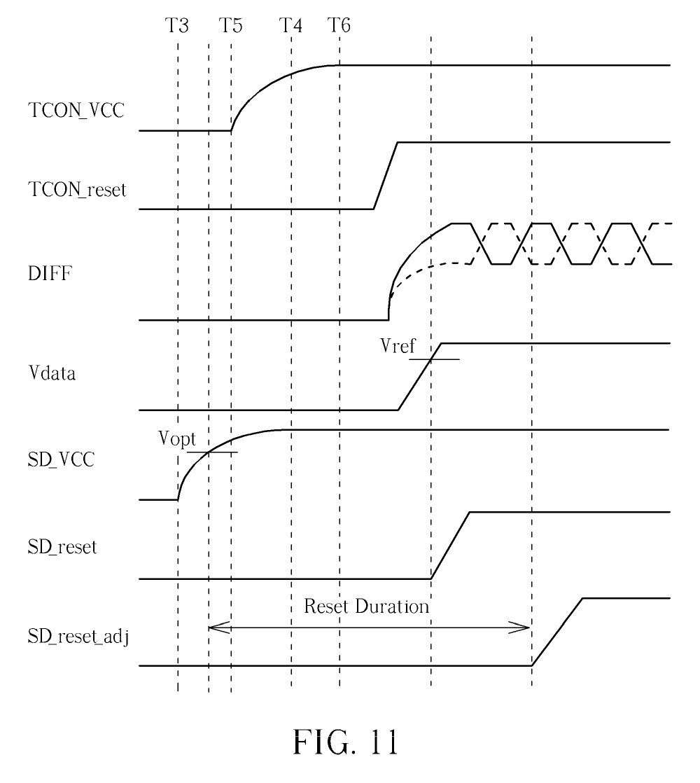

In FIG. 11, the supply voltage SD_VCC is activated earlier than both of the reset signal TCON_reset and the supply voltage TCON_VCC are. The supply voltage SD_VCC is activated at the time point T3 and becomes stable after the time point T4, whereas the supply voltage TCON_VCC is activated at the time point T5 and becomes stable after the time point T6. The source driver begins to reset at the time point where the supply voltage SD_VCC is over the voltage level Vopt until the time point where the reset adjusting signal SD_reset_adj transits up to the high voltage level. The data voltage signal Vdata in FIG. 11 also has become stable before the source driver accomplishes reset.

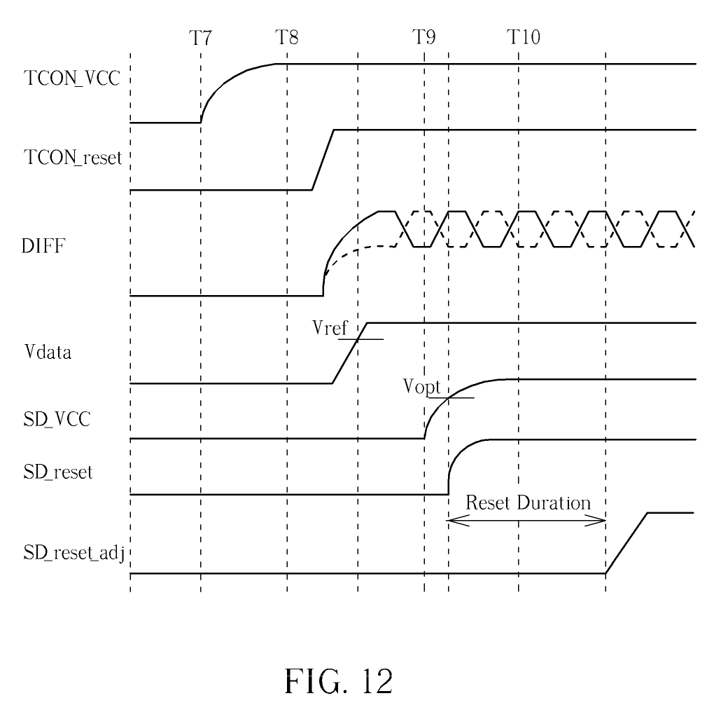

In FIG. 12, the supply voltage SD_VCC is activated at the time point T9 and becomes stable at the time point T10, later than the time points 7 and 8 where the supply voltage TCON_VCC is activated and becomes stable, respectively. The data voltage signal Vdata is over the reference voltage Vref at the time point T9 and then enters the stable state. When the supply voltage SD_VCC is over the voltage level Vopt, the data voltage signal Vdata begins to be compared with the reference voltage Vref, and meanwhile the source driver starts reset until the reset adjusting signal SD_reset_adj transits up to the high voltage level. From FIG. 12, the source driver can prolong reset duration with the reset adjusting signal SD_reset_adj even though the data voltage signal Vdata is over the reference voltage Vref before the source driver is powered on.

From FIGS. 10-12, the data outputted by the timing controller has entered the stable state when the source driver accomplishes reset irrespective of the power-on sequence. Thus, the source driver can avoid reception of invalid data, resulting in system errors.

Please note that, in the abovementioned embodiments of the present invention, the reset signal SD_reset and the reset adjusting signal SD_reset_adj are not limited to be at the low voltage level in default. The high voltage level is also an alternative for the default setting.

In conclusion, the embodiments of the present invention determines whether the output data of the timing controller is stable or not by detecting the differential signal including the output data to determine the reset duration of the source driver. Therefore, with the data trigger reset device of the present invention, the electronic devices in the electronic system can significantly resolve data receiving errors due to reset and also achieve flexibility on the power-on sequence.

Those skilled in the art will readily observe that numerous modifications and alterations of the device and method may be made while retaining the teachings of the invention.

What is claimed is:

1. A data trigger reset device for an electronic device, the data trigger reset device comprising:
a voltage converter for receiving and converting an input signal to generate a data voltage signal; and
a voltage comparator coupled to the voltage converter, for comparing the data voltage signal with a reference voltage to generate a reset signal for resetting the electronic device.

2. The data trigger reset device of claim 1 further comprising:
a reset signal adjuster coupled to the voltage comparator, for delaying the reset signal to generate a reset adjusting signal.

3. The data trigger reset device of claim 2, wherein the reset signal adjuster comprises:
a buffer for receiving the reset signal;
a capacitor coupled to the buffer and a grounded terminal, for generating a first voltage according to the reset signal; and
a Schmitt trigger coupled to the buffer and the capacitor, for generating the reset adjusting signal according to the first voltage.

4. The data trigger reset device of claim 1, wherein the input signal is a differential signal.

5. The data trigger reset device of claim 1, wherein the input signal is a multilevel voltage signal.

6. The data trigger reset device of claim 1, wherein the voltage converter is a voltage divider.

7. The data trigger reset device of claim 1, wherein the electronic device is a source driver of a display.

8. A data trigger reset method for an electronic device, the data trigger reset method comprising:
receiving an input signal;
converting the input signal to generate a data voltage signal; and
comparing the data voltage signal with a reference voltage to generate a reset signal for resetting the electronic device.

9. The data trigger reset method of claim 8 further comprising:
delaying the reset signal to generate a reset adjusting signal; and
resetting the electronic device according to the reset adjusting signal.

10. The data trigger reset method of claim 8, wherein the input signal is a differential signal.

11. The data trigger reset method of claim 8, wherein the input signal is a multilevel voltage signal.

12. The data trigger reset method of claim 8, wherein the electronic device is a source driver of a display.

13. A data trigger reset device for a display, the data trigger reset device comprising:
a timing controller for generating an input signal; and
a source driver coupled to the timing controller, the source driver comprising:
a voltage converter for receiving and converting the input signal to generate a data voltage signal; and
a voltage comparator coupled to the voltage converter, for comparing the data voltage signal with a reference voltage to generate a reset signal for resetting the source driver.

14. The data trigger reset device of claim 13, wherein the source driver further comprises:
a reset signal adjuster coupled to the voltage comparator, for delaying timing of the reset signal to generate a reset adjusting signal.

15. The data trigger reset device of claim 14, wherein the reset signal adjuster comprises:
a buffer for receiving the reset signal;
a capacitor coupled to the buffer and a grounded terminal, for generating a first voltage according to the reset signal; and
a Schmitt trigger coupled to the buffer and the capacitor, for generating the reset adjusting signal according to the first voltage.

16. The data trigger reset device of claim 13, wherein the input signal is a differential signal.

17. The data trigger reset device of claim 13, wherein the input signal is a multilevel voltage signal.

18. The data trigger reset device of claim 13, wherein the voltage converter is a voltage divider.
